(19) United States
(12) Patent Application Publication
(10) Pub. No.: US 2020/0196723 A1
(43) Pub. Date: Jun. 25, 2020

(54) RADIOFREQUENCY ELECTROMAGNETIC RADIATION-SHIELDING SMART-KEY HOLDER AND METHODS THEREOF

(71) Applicant: LUCKY LINE PRODUCTS, INC., San Diego, CA (US)

(72) Inventors: William Fleming, San Diego, CA (US); Paul Northeimer, San Diego, CA (US)

(73) Assignee: LUCKY LINE PRODUCTS, INC., San Diego, CA (US)

(21) Appl. No.: 16/721,734

(22) Filed: Dec. 19, 2019

Related U.S. Application Data
(60) Provisional application No. 62/782,266, filed on Dec. 19, 2018.

(51) Int. Cl. A45C 11/32; B32B 5/02; B32B 27/12; B32B 27/36; B32B 5/26; H05K 9/00

(52) U.S. Cl. CPC A45C 11/32; B32B 5/024; B32B 27/12; B32B 27/36; B32B 5/26; A45C 2011/322; H05K 9/0084; B32B 2262/0276; B32B 2307/212; B32B 2439/46; H05K 9/0007

(57) ABSTRACT

A two-piece EMR-shielding smart-key holder is disclosed including a first piece having a cavity within a body sized to hold one or more smart keys, an EMR-shielding layer lining the cavity, and a first piece of a touch fastener incorporated into a second face of the body. A second piece of the smart-key holder includes a second piece of the touch fastener. A method is also disclosed including adhering a second face of the second piece of the smart-key holder to an object's surface leaving a first face of the second piece having the second piece of the touch fastener exposed. The method also includes fastening the first and second pieces of the smart-key holder together by way of complementary touch-fastener features, thereby attaching the first piece to the object's surface shielding the one or more smart keys from at least radiofrequency communications in place on the object's surface.

### PRIORITY

This application claims the benefit of priority to U.S. Provisional Patent Application No. 62/782,266, filed Dec. 19, 2018, which is incorporated by reference in its entirety into this application.

### BACKGROUND

Smart-key systems for motor vehicles that enable electronic access and authorization for operation of such motor vehicles by way of radiofrequency communications face a sophisticated threat known as a “relay attack,” which permits thieves between such motor vehicles and their smart keys to electronically access and operate the motor vehicles without owners' awareness. The relay attack requires two thieves working in cooperation with each other, wherein each thief carries an attack kit capable of intercepting radiofrequency communications from either a motor vehicle or the motor vehicle's smart key and amplifying the radiofrequency communications at a time of forwarding the radiofrequency communications to the other thief

In addition, a precautionary feature built into most motor vehicles keeps such motor vehicles from locking when their corresponding smart keys are kept or otherwise hidden inside of or on the motor vehicles. This is due to the foregoing radiofrequency communications between the motor vehicles and their corresponding smart keys.

Provided herein is a radiofrequency electromagnetic radiation-shielding smart-key holder and methods thereof that address a need to thwart relay attacks. In addition, the radiofrequency electromagnetic radiation-shielding smart-key holder overcomes the foregoing precautionary feature built into most vehicles, thereby allowing smart keys to be kept or hidden inside of or on such motor vehicles.

### SUMMARY

Disclosed herein an electromagnetic radiation (“EMR”)-shielding smart-key holder including, in some embodiments, a multilayered body, a cavity within the body sized to hold one or more smart keys, an EMR-shielding layer lining the cavity, and a toolless, reusable fastening means for fastening the smart-key holder to a surface of an object as well as unfastening the smart- key holder from the surface.

In some embodiments, the fastening means is two-piece touch fastener. A first piece of the touch fastener is incorporated into a face of the body, and a second piece of the touch fastener is incorporated into a separate, surface-adherable piece of the EMR-shielding smart-key holder.

In some embodiments, the EMR-shielding smart-key holder also includes a flap extending from the body configured to fold over the cavity.

In some embodiments, the EMR-shielding layer extends from the cavity into the flap such that a portion of the EMR-shielding layer is also configured to fold over the cavity.

In some embodiments, the first piece of the touch fastener is configured to fasten together with the second piece of the touch fastener to fasten the EMR-shielding smart-key holder to a surface of an object. The first piece of the touch fastener is also configured to fasten together with the flap to fasten the flap to the body to close the cavity upon folding the flap over the cavity.

In some embodiments, the EMR-shielding layer is a metallized fabric configured to shield one or more smart keys in the cavity from at least radiofrequency communications.

Also disclosed herein is an EMR-shielding smart-key holder including, in some embodiments, a multilayered body having a first face and a second face, a cavity within the body sized to hold one or more smart keys, an EMR-shielding layer lining the cavity, and a flap extending from the body configured to fold over the cavity and fasten with the second face of the body. The EMR-shielding layer extends from the cavity into the flap such that a portion of the EMR-shielding layer is also configured to fold over the cavity. The EMR-shielding smart-key holder also includes a two-piece touch fastener in which a first piece of the touch fastener is incorporated into the second face of the body and a second piece of the touch fastener is incorporated into a separate, surface-adherable piece of the EMR-shielding smart-key holder.

In some embodiments, the first piece of the touch fastener is configured to fasten together with the second piece of the touch fastener to fasten the EMR-shielding smart-key holder to a surface of an object. The first piece of the touch fastener is also configured to fasten together with the flap to fasten the flap to the second face of the body to close the cavity upon folding the flap over the cavity.

In some embodiments, the first face of the body is part of at least a first layer of the body formed of a synthetic textile.

In some embodiments, the second face of the body is part of at least a second layer of the body formed of a synthetic backing including a plurality of loops on the synthetic backing.

In some embodiments, a second piece of the touch fastener includes a plurality of hooks on a first face of the surface-adherable piece of the EMR-shielding smart-key holder. The second piece of the touch fastener also includes a pressure-sensitive adhesive on a second face of the surface-adherable piece.

In some embodiments, the flap includes a plurality of hooks on at least a portion of the flap configured to fasten with the second face of the body.

In some embodiments, the EMR-shielding layer is a metallized fabric configured to shield one or more smart keys in the cavity from radiofrequency communications.

Also disclosed herein is a method of an EMR-shielding smart-key holder including, in some embodiments, adhering a second face of a second, surface-adherable piece of the EMR-shielding smart-key holder to a surface of an object leaving a first face of the second piece exposed, wherein the first face of the second piece includes a second set of touch-fastener features. The method also includes placing one or more smart keys into an EMR-shielded cavity within a multilayered body of a first piece of the EMR-shielding smart-key holder, wherein a second face of the first piece includes a first set of touch-fastener features complementary to the second set of touch-fastener features. The method also includes fastening the first and second pieces of the EMR-shielding smart-key holder together by way of the complementary touch-fastener features, thereby attaching the first piece to the surface of the object. The method also includes shielding the one or more smart keys from at least radiofrequency communications in place on the surface of the object.

In some embodiments, the method also includes unfastening the first piece of the EMR-shielding smart-key holder from the second piece, thereby removing the second piece from the surface of the object.

In some embodiments, the method also includes removing at least one smart key of the one or more smart keys from the cavity of the EMR-shielding smart-key holder or adding an additional smart key to the one or more smart keys within the cavity.

In some embodiments, the method also includes refastening the first and second pieces of the EMR-shielding smart-key holder together by way of the complementary touch-fastener features, thereby reattaching the first piece to the surface of the object.

In some embodiments, the method also includes removing a separating layer from the second piece of the EMR-shielding smart-key holder to expose a pressure-sensitive adhesive on the second face of the surface-adherable piece for adhering the second face of the second piece to the surface of the object.

In some embodiments, the method also includes folding a flap extending from the body of the first piece of the EMR-shielding smart-key holder onto the second face of the first piece to enclose the one or more smart keys in the cavity, wherein an EMR-shielding layer of the cavity extends into the flap such that the EMR-shielding layer folds over the cavity when folding the flap onto the second face of the first piece. The flap also includes a third set of touch-fastener features identical to the second set of touch-fastener features for fastening the flap and the second face of the first piece together by way of the complementary touch-fastener features.

These and other features of the concepts provided herein will become more apparent to those of skill in the art in view of the accompanying drawings and following description, which disclose particular embodiments of such concepts in greater detail.

### DRAWINGS

FIG. 1 illustrates a first view of an EMR-shielding smart-key holder in accordance with some embodiments.

FIG. 2 illustrates a second view of the EMR-shielding smart-key holder in accordance with some embodiments.

FIG. 3 illustrates a third view of the EMR-shielding smart-key holder in accordance with some embodiments.

FIG. 4 illustrates a first view of a first piece of the EMR-shielding smart-key holder in accordance with some embodiments.

FIG. 5 illustrates a second view of the first piece of the EMR-shielding smart-key holder in accordance with some embodiments.

FIG. 6 illustrates a first view of a second piece of the EMR-shielding smart-key holder in accordance with some embodiments.

FIG. 7A illustrates a two-piece touch fastener of the EMR-shielding smart-key holder in accordance with some embodiments.

FIG. 7B illustrates a three-piece touch fastener of the EMR-shielding smart-key holder in accordance with some embodiments.

FIG. 8 illustrates a method of the EMR-shielding smart-key in accordance with some embodiments.

### DESCRIPTION

Before some particular embodiments are disclosed in greater detail, it should be understood that the particular embodiments disclosed herein do not limit the scope of the concepts provided herein. It should also be understood that a particular embodiment disclosed herein can have features that can be readily separated from the particular embodiment and optionally combined with or substituted for features of any of a number of other embodiments disclosed herein.

Regarding terms used herein, it should also be understood the terms are for the purpose of describing some particular embodiments, and the terms do not limit the scope of the concepts provided herein. Ordinal numbers (e.g., first, second, third, etc.) are generally used to distinguish or identify different features or steps in a group of features or steps, and do not supply a serial or numerical limitation. For example, “first,” “second,” and “third” features or steps need not necessarily appear in that order, and the particular embodiments including such features or steps need not necessarily be limited to the three features or steps. Labels such as “left,” “right,” “front,” “back,” “top,” “bottom,” “forward,” “reverse,” “clockwise,” “counter clockwise,” “up,” “down,” and the like are used for convenience and are not intended to imply, for example, any particular fixed location, orientation, or direction. Instead, such labels are used to reflect, for example, relative location, orientation, or directions. Singular forms of “a,” “an,” and “the” include plural references unless the context clearly dictates otherwise.

Unless defined otherwise, all technical and scientific terms used herein have the same meaning as commonly understood by those of ordinary skill in the art.

Again, smart-key systems for motor vehicles that enable electronic access and authorization for operation of such motor vehicles by way of radiofrequency communications face a sophisticated threat known as a “relay attack,” which permits thieves between such motor vehicles and their smart keys to electronically access and operate the motor vehicles without owners' awareness. The relay attack requires two thieves working in cooperation with each other, wherein each thief carries an attack kit capable of intercepting radiofrequency communications from either a motor vehicle or the motor vehicle's smart key and amplifying the radiofrequency communications at a time of forwarding the radiofrequency communications to the other thief

In addition, a precautionary feature built into most motor vehicles keeps such motor vehicles from locking when their corresponding smart keys are kept or otherwise hidden inside of or on the motor vehicles. This is due to the foregoing radiofrequency communications between the motor vehicles and their corresponding smart keys.

Provided herein is a radiofrequency electromagnetic radiation-shielding smart-key holder and methods thereof that address a need to thwart relay attacks. In addition, the radiofrequency electromagnetic radiation-shielding smart-key holder overcomes the foregoing precautionary feature built into most vehicles, thereby allowing smart keys to be kept or hidden inside of or on such motor vehicles.

For example, a two-piece EMR-shielding smart-key holder is disclosed including a first piece having a cavity within a body sized to hold one or more smart keys, an EMR-shielding layer lining the cavity, and a first piece of a touch fastener incorporated into a second face of the body. A second piece of the smart-key holder includes a second piece of the touch fastener. A method is also disclosed including adhering a second face of the second piece of the smart-key holder to an object's surface leaving a first face of the second piece having the second piece of the touch fastener exposed. The method also includes fastening the first and second pieces of the smart-key holder together by way of complementary touch-fastener features, thereby attaching the first piece to the object's surface shielding the one or more smart keys from at least radiofrequency communications in place on the object's surface.

### EMR-Shielding Smart-Key Holder

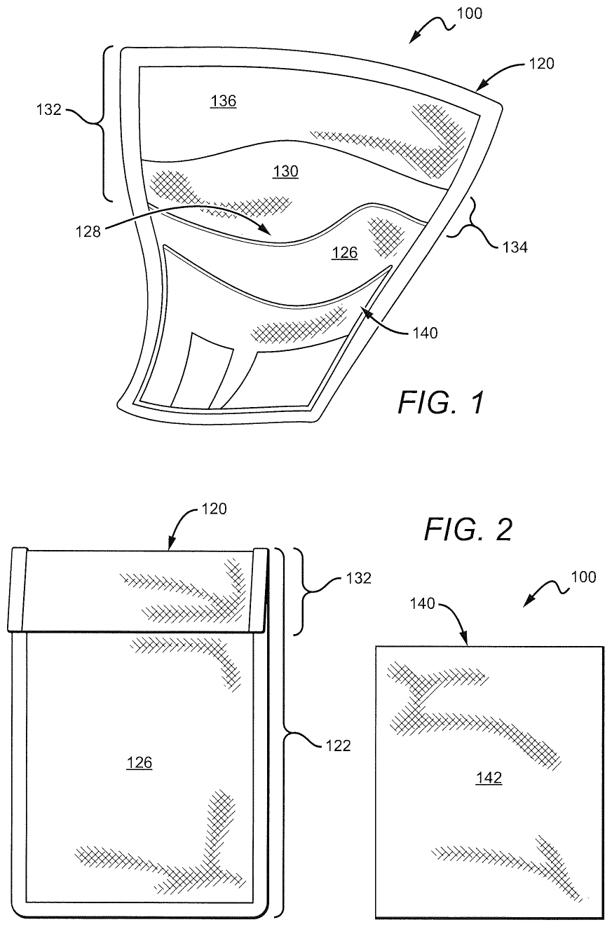

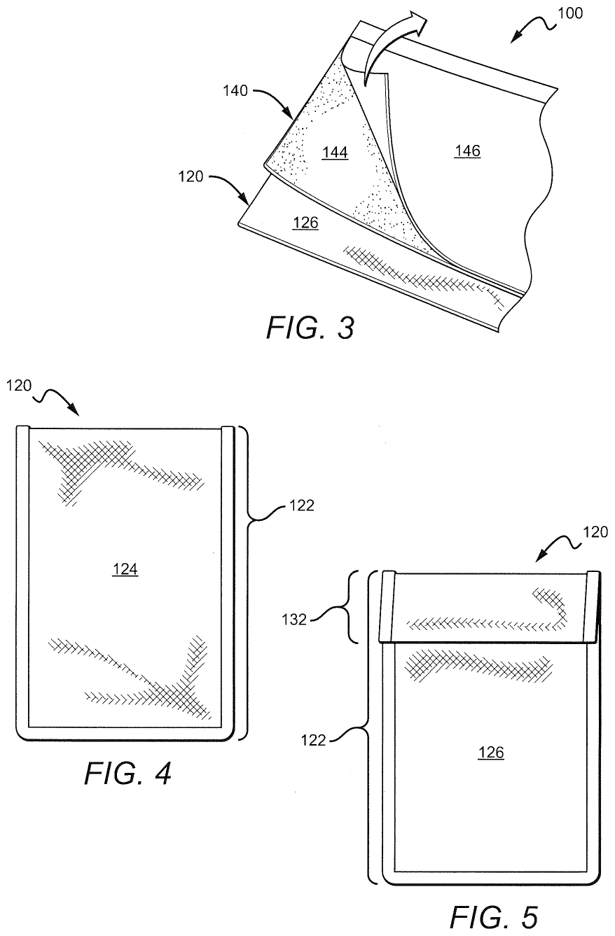

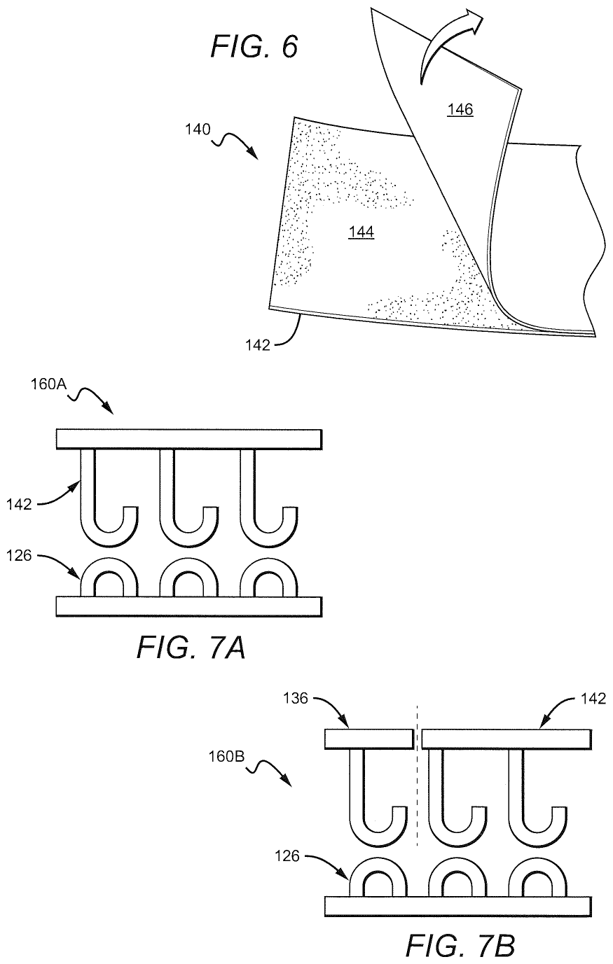

FIGS. 1-3 illustrate different views of an EMR-shielding smart-key holder 100 in accordance with some embodiments. FIGS. 4 and 5 illustrate different views of a first piece 120 of the EMR-shielding smart-key holder 100 in accordance with some embodiments, while FIG. 6 illustrates a view of a second piece 140 of the EMR-shielding smart-key holder 100 in accordance with some embodiments.

As shown, the EMR-shielding smart-key holder 100 includes two separable pieces 120, 140 of the EMR-shielding smart-key holder 100.

The first piece 120 of the EMR-shielding smart-key holder 100 includes a multilayered body 122 having a first, or front, face 124 and a second, or back, face 126, a cavity 128 within the body 122 sized to hold one or more smart keys or other electronic devices at risk of being compromised by way of radiofrequency communications, and an EMR-shielding layer 130 lining an entirety of the cavity 128. The first piece 120 of the EMR-shielding smart-key holder 100 also includes a flap 132 extending from a main portion of the body 122, wherein the flap 132 is configured to fold over the cavity 128. The EMR-shielding layer 130 extends from the cavity 128 into the flap 132 such that a portion 134 of the EMR-shielding layer 130 is also configured to fold over the cavity 128.

The front face 124 of the first piece 120 of the EMR-shielding smart-key holder 100 is part of at least a first layer of the body 122 formed of a synthetic textile such as nylon having any weave of a number of different weaves such as an Oxford weave. The back face 126 of the first piece 120 of the EMR-shielding smart-key holder 100 is part of at least a second layer of the body 122 formed of a synthetic backing such as nylon. Hooks or loops of a hook-and-loop fastener such as one of the hook-and-loop fasteners set forth herein can be incorporated into the synthetic backing. The EMR-shielding layer 130 is a metallized fabric (e.g., a metallized nylon, a metallized polyester including a blend of 18-24% nickel and 13-20% copper such as a blend of 23% copper and 20% nickel) configured to shield one or more smart keys in the cavity 128 from at least radiofrequency communications, for example, at a 70-84 dB shielding rating, or more, such as 80 dB. Indeed, the EMR-shielding layer 130 is configured to shield one or more smart keys in the cavity 128 from radiofrequency communications even when the EMR-shielding smart-key holder 100 including a spare smart key is hidden within the auto mobile that the spare smart key provides authorization to operate. Normally, the spare smart key within the motor vehicle would prevent the motor vehicle from locking when an operator of the motor vehicle exits with the main smart key. Combination of the foregoing layers into the multilayered body 122 of the EMR-shielding smart-key holder 100 waterproofs the EMR-shielding smart-key holder 100.

The second piece 140 of the EMR-shielding smart-key holder 100 is a separate, surface-adherable piece of the EMR-shielding smart-key holder 100 including a first, or front, face 142, and a second, or back, face 144. A high-tack adhesive such as a pressure-sensitive adhesive on the back face 144 of the second piece 140 is configured for adhering the second piece 140 to an object's surface once a separating layer 146 is removed, or peeled, from the back face 144 of the second piece 140. The surface to which the second piece 140 of the EMR-shielding smart-key holder 100 can be adhered includes an interior surface or an exterior surface, preferably an inconspicuous surface that is not conventionally used to throw off thieves. The interior surface includes, but is not limited to, any surface within a house, office, or motor vehicle such as a surface under a table, within a cabinet, under a dashboard, or under a seat. The exterior surface includes, but is not limited to, any surface outside a motor such as a surface under the motor vehicle, an inner surface of a motor vehicle's wheel rim, or the like, which are not conventionally used due to adherence difficulties. Due to such adherence difficulties, adhering the second piece 140 of the EMR-shielding smart-key holder 100 to an object's surface is facilitated by first cleaning the object's surface.

The front and back faces 142, 144 of the second piece 140 of the EMR-shielding smart-key holder 100 is part of at least a synthetic backing such as nylon. Hooks or loops of a hook-and-loop fastener such as one of the hook-and-loop fasteners set forth herein can be incorporated into the synthetic backing.

FIG. 7A illustrates a two-piece touch fastener 160A of the EMR-shielding smart- key holder 100 in accordance with some embodiments. FIG. 7B illustrates a three-piece touch fastener 160B of the EMR-shielding smart-key holder 100 in accordance with some embodiments. The touch fasteners 160A and 160B are collectively referenced herein as the touch fastener 160 unless a distinction is made between the touch fasteners 160A and 160B, in which case, the two-piece touch fastener 160A and the three-piece touch fastener 160B are individually referenced.

The EMR-shielding smart-key holder 100 also includes a toolless, reusable fastening means for fastening the EMR-shielding smart-key holder 100 to an object's surface, as well as unfastening the smart-key holder 100 from the object's surface. In some embodiments, the fastening means is the collective touch fastener 160 of FIGS. 7A an 7B, which is a hook-and-loop fastener. However, the touch fastener 160 is not limited to a hook-and-loop fastener; that is, complementary features other than any one or both of the hooks and loops can be implemented in the touch fastener 160. For example, the touch fastener 160 can alternatively have a mushroom-tipped pillar for a loop-hooking element instead of a hook. In some other examples, the touch fastener 160 can be a self-engaging mushroom fastener such as a Duotec® fastener (Gottlieb Binder GmbH & Co KG, Holzgerlingen, Germany) or a Dual Lock™ Reclosable Fastener (3M, St. Paul, Minn., USA), a Microplast® fastener (Gottlieb Binder GmbH & Co KG, Holzgerlingen, Germany), or a slidingly engaging fastener such as that described in U.S. Pat. No. 7,246,416, which is hereby incorporated herein by reference in its entirety.

At least a first piece of the touch fastener 160 is incorporated into the back face 126 of the first piece 120 of the EMR-shielding smart-key holder 100, and at least a second piece of the touch fastener 160 is incorporated into the front face 142 of the second piece 140 of the EMR-shielding smart-key holder 100. As shown, the back face 126 of the first piece 120 and the front face 142 of the second piece 140 of the EMR-shielding smart-key holder 100 are respectively shown with a number of loops and a number of hooks of a hook-and-loop fastener; however, the configuration can be reversed such that the back face 126 of the first piece 120 has the hooks while the front face 142 of the second piece 140 has the loops of the hook-and-loop fastener. Nevertheless, the first piece of the touch fastener 160 is configured to fasten together with the second piece of the touch fastener 160 to fasten the EMR-shielding smart-key holder 100 to an object's surface when the back face 144 of the second piece 140 is adhered to the object's surface.

A third piece of the touch fastener 160 can be incorporated into a back face 136 of the flap 132 for the three-piece touch fastener 160B of the EMR-shielding smart-key holder 100 shown in FIGS. 1 and 7B. As shown, the back face 126 of the first piece 120 of the EMR-shielding smart-key holder 100 has a number of loops of a hook-and-loop fastener while both the front face 142 of the second piece 140 and the back face 136 of the flap 132 have a number of hooks of the hook-and-loop fastener; however, the configuration can be reversed such that the back face 126 of the first piece 120 has the hooks while both the front face 142 of the second piece 140 and the back face 136 of the flap 132 have the loops of the hook-and-loop fastener. Nevertheless, the first piece of the touch fastener 160 is configured to fasten together with the second piece of the touch fastener 160B to fasten the EMR-shielding smart-key holder 100 to an object's surface when the back face 144 of the second piece 140 is adhered to the object's surface. And, in addition, the first piece of the touch fastener 160B is configured to fasten together with the third piece of the touch fastener 160B to fasten the flap 132 to the body 122 of the EMR-shielding smart-key holder 100 to close the cavity 128 upon folding the flap 132 over the cavity 128. In the absence of the third piece of the touch fastener 160B such as in embodiments of the EMR-shielding smart-key holder 100 having the two-piece fastener 160A, a zipper, buttons, snaps, or the like can be used to fasten the flap 132 to the body 122 of the EMR-shielding smart-key holder 100 to close the cavity 128 upon folding the flap 132 over the cavity 128.

### Methods

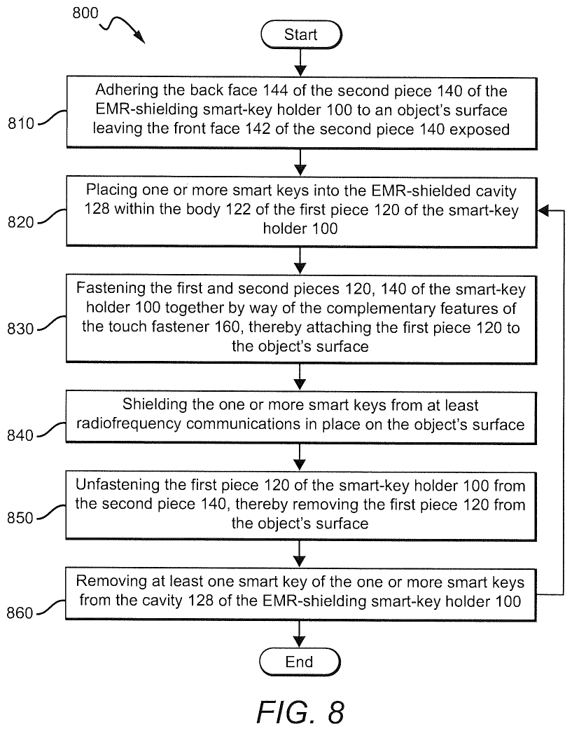

FIG. 8 illustrates a method 800 of the EMR-shielding smart-key 100 having a number of operations in accordance with some embodiments.

As shown, a first operation 810 includes adhering the back face 144 of the second, surface-adherable piece 140 of the EMR-shielding smart-key holder 100 to an object's surface leaving the front face 142 of the second piece 140 exposed. Adhering the back face 144 of the second piece 140 of the EMR-shielding smart-key holder 100 to an object's surface includes cleaning the object's surface and removing the separating layer 146 from the second piece 140 to expose a pressure-sensitive adhesive on the back face 144 of the second piece 140 for adhering the back face 144 of the second piece 140 to the object's surface. The front face 142 of the second piece 140 of the EMR-shielding smart-key holder 100 includes a second set of touch-fastener features such as the hooks of the touch fastener 160 shown in FIGS. 7A and 7B.

A second operation 820 includes placing one or more smart keys into the EMR- shielded cavity 128 within the multilayered body 122 of the first piece 120 of the EMR-shielding smart-key holder 100. The back face 126 of the first piece 120 of the EMR-shielding smart-key holder 100 includes a first set of touch-fastener features such as the loops of the touch fastener 160 shown in FIGS. 7A and 7B, which are complementary features to the second set of touch-fastener features on the front face 142 of the second piece 140 of the of the EMR-shielding smart-key holder 100.

Placing one or more smart keys into the EMR-shielded cavity 128 includes folding the flap 132 extending from the body 122 of the first piece 120 of the EMR-shielding smart-key holder 100 onto the back face 126 of the first piece 120 to enclose the one or more smart keys in the cavity 128. The EMR-shielding layer 130 of the cavity extends into the flap 132 such that the EMR-shielding layer 130 folds over the cavity 128 when folding the flap 132 onto the back face 126 of the first piece 120 of the EMR-shielding smart-key holder 100. Folding the EMR-shielding layer 130 over the cavity 128 ensures that the one or more smart keys are fully and properly shielded by the EMR-shielding smart-key holder 100. The flap 132 also includes a third set of touch-fastener features such as the hooks of the touch fastener 160B shown in FIG. 7B, which are identical to the second set of touch-fastener features of the front face 142 of the second piece 140 of the EMR-shielding smart-key holder 100, for fastening the back face 136 of the flap 132 and the back face 126 of the first piece 120 together by way of the complementary touch-fastener features.

A third operation 830 includes fastening the first and second pieces 120, 140 of the EMR-shielding smart-key holder 100 together by way of the complementary touch-fastener features of the touch fastener 160, thereby attaching the first piece 120 to the object's surface.

A fourth operation 840 includes shielding the one or more smart keys from at least radiofrequency communications in place on the object's surface.

A fifth operation 850 includes unfastening the first piece 120 of the EMR-shielding smart-key holder 100 from the second piece 140, thereby removing the first piece 120 from the object's surface.

A sixth operation 860 includes removing at least one smart key of the one or more smart keys from the cavity 128 of the EMR-shielding smart-key holder 100.

Operations 820, 830, 840, 850, and 860 of the method 800 of the EMR-shielding smart-key holder 100 can be repeated any of a number of times including adding an additional smart key to the one or more smart keys within the cavity 128 in accordance with the operation 820, as well as refastening the first and second pieces 120, 140 of the EMR-shielding smart-key holder 100 together by way of the complementary touch-fastener features of the touch fastener 160, thereby reattaching the first piece to the object's surface, which is in accordance with the operation 830.

While some particular embodiments have been disclosed herein, and while the particular embodiments have been disclosed in some detail, it is not the intention for the particular embodiments to limit the scope of the concepts provided herein. Additional adaptations and/or modifications can appear to those of ordinary skill in the art, and, in broader aspects, these adaptations and/or modifications are encompassed as well. Accordingly, departures may be made from the particular embodiments disclosed herein without departing from the scope of the concepts provided herein.

What is claimed is:

1. An electromagnetic radiation (“EMR”)-shielding smart-key holder, comprising:
a multilayered body;
a cavity within the body sized to hold one or more smart keys;
an EMR-shielding layer lining the cavity; and
a toolless, reusable fastening means for fastening the smart-key holder to a surface of an object as well as unfastening the smart-key holder from the surface.

2. The EMR-shielding smart-key holder of claim 1, wherein the fastening means is two-piece touch fastener in which a first piece of the touch fastener is incorporated into a face of the body and a second piece of the touch fastener is incorporated into a separate, surface-adherable piece of the EMR-shielding smart-key holder.

3. The EMR-shielding smart-key holder of claim 2, further comprising:
a flap extending from the body configured to fold over the cavity,
wherein the first piece of the touch fastener is configured to independently fasten together with the second piece of the touch fastener and the flap to respectively fasten i) the EMR-shielding smart-key holder to a surface of an object and ii) the flap to the body to close the cavity upon folding the flap over the cavity.

4. The EMR-shielding smart-key holder of claim 3, wherein the EMR-shielding layer extends from the cavity into the flap such that a portion of the EMR-shielding layer is also configured to fold over the cavity.

5. The EMR-shielding smart-key holder of claim 1, further comprising:
a flap extending from the body configured to fold over the cavity.

6. The EMR-shielding smart-key holder of claim 5, wherein the EMR-shielding layer extends from the cavity into the flap such that a portion of the EMR-shielding layer is also configured to fold over the cavity.

7. The EMR-shielding smart-key holder of claim 1, wherein the EMR-shielding layer is a metallized fabric configured to shield one or more smart keys in the cavity from at least radiofrequency communications.

8. An electromagnetic radiation (“EMR”)-shielding smart-key holder, comprising:
a multilayered body having a first face and a second face;
a cavity within the body sized to hold one or more smart keys;
an EMR-shielding layer lining the cavity;
a flap extending from the body configured to fold over the cavity and fasten with the second face of the body,
wherein the EMR-shielding layer extends from the cavity into the flap such that a portion of the EMR-shielding layer is also configured to fold over the cavity; and
a two-piece touch fastener in which a first piece of the touch fastener is incorporated into the second face of the body and a second piece of the touch fastener is incorporated into a separate, surface-adherable piece of the EMR-shielding smart-key holder.

9. The EMR-shielding smart-key holder of claim 8, wherein the first piece of the touch fastener is configured to independently fasten together with the second piece of the touch fastener and the flap to respectively fasten i) the EMR-shielding smart-key holder to a surface of an object and ii) the flap to the second face of the body to close the cavity upon folding the flap over the cavity.

10. The EMR-shielding smart-key holder of claim 8, wherein the first face of the body is part of at least a first layer of the body formed of a synthetic textile.

11. The EMR-shielding smart-key holder of claim 8, wherein the second face of the body is part of at least a second layer of the body formed of a synthetic backing including a plurality of loops on the synthetic backing.

12. The EMR-shielding smart-key holder of claim 8, wherein a second piece of the touch fastener includes a plurality of hooks on a first face of the surface-adherable piece of the EMR-shielding smart-key holder and a pressure-sensitive adhesive on a second face of the surface-adherable piece.

13. The EMR-shielding smart-key holder of claim 8, wherein the flap includes a plurality of hooks on at least a portion of the flap configured to fasten with the second face of the body.

14. The EMR-shielding smart-key holder of claim 8, wherein the EMR-shielding layer is a metallized fabric configured to shield one or more smart keys in the cavity from at least radiofrequency communications.

15. A method of an electromagnetic radiation (“EMR”)-shielding smart-key holder, comprising:
adhering a second face of a second, surface-adherable piece of the EMR-shielding smart-key holder to a surface of an object leaving a first face of the second piece exposed,
wherein the first face of the second piece includes a second set of touch-fastener features;
placing one or more smart keys into an EMR-shielded cavity within a multilayered body of a first piece of the EMR-shielding smart-key holder,
wherein a second face of the first piece includes a first set of touch-fastener features complementary to the second set of touch-fastener features;
fastening the first and second pieces of the EMR-shielding smart-key holder together by way of the complementary touch-fastener features, thereby attaching the first piece to the surface of the object; and
shielding the one or more smart keys from at least radiofrequency communications in place on the surface of the object.

16. The method of claim 15, further comprising:
unfastening the first piece of the EMR-shielding smart-key holder from the second piece, thereby removing the first piece from the surface of the object.

17. The method of claim 16, further comprising:
removing at least one smart key of the one or more smart keys from the cavity of the EMR-shielding smart-key holder or adding an additional smart key to the one or more smart keys within the cavity.

18. The method of claim 16, further comprising:
refastening the first and second pieces of the EMR-shielding smart-key holder together by way of the complementary touch-fastener features, thereby reattaching the first piece to the surface of the object.

19. The method of claim 15, further comprising:
removing a separating layer from the second piece of the EMR-shielding smart-key holder to expose a pressure-sensitive adhesive on the second face of the surface- adherable piece for adhering the second face of the second piece to the surface of the object.

20. The method of claim 15, further comprising:
folding a flap extending from the body of the first piece of the EMR-shielding smart-key holder onto the second face of the first piece to enclose the one or more smart keys in the cavity,
wherein an EMR-shielding layer of the cavity extends into the flap such that the EMR-shielding layer folds over the cavity when folding the flap onto the second face of the first piece, and
wherein the flap includes a third set of touch-fastener features identical to the second set of touch-fastener features for fastening the flap and the second face of the first piece together by way of the complementary touch-fastener features.
